(19) United States
(12) Patent Application Publication
(10) Pub. No.: US 2017/0338984 A1
(43) Pub. Date: Nov. 23, 2017

(54) RECEIVER COUPLED TO AN INFINITE IMPULSE RESPONSE (IIR) COMPENSATION FILTER

(71) Applicant: QUALCOMM Incorporated, San Diego, CA (US)

(72) Inventors: Kiran Kiran, Pleasanton, CA (US); Manikandan Chandrasekar, Bangalore (IN); Swaroop Venkatesh, San Ramon, CA (US)

(21) Appl. No.: 15/162,301

(22) Filed: May 23, 2016

(51) Int. Cl. H04L 27/148; H03H 17/04; H04L 25/08; H04L 27/26; H04L 27/00; H03H 17/00

(52) U.S. Cl. CPC H04L 27/148; H04L 27/26; H04L 27/0002; H03H 17/04; H04L 25/08; H03H 2017/009

(57) ABSTRACT

A device for communication includes a receiver and a tuned infinite impulse response (IIR) compensation filter. The receiver is coupled to an in-phase path and a quadrature path. The tuned IIR compensation filter is coupled to one of the in-phase path or the quadrature path.

### I. FIELD

The present disclosure is generally related to a receiver coupled to an infinite impulse response (IIR) compensation filter.

### II. DESCRIPTION OF RELATED ART

Advances in technology have resulted in smaller and more powerful computing devices. For example, there currently exist a variety of portable personal computing devices, including wireless telephones such as mobile and smart phones, watches, tablets and laptop computers that are small, lightweight, and easily carried by users. These devices can communicate voice and data packets over wireless networks. Further, many such devices incorporate additional functionality such as a digital still camera, a digital video camera, a digital recorder, and an audio file player. Also, such devices can process executable instructions, including software applications, such as a web browser application, that can be used to access the Internet. As such, these devices can include significant computing capabilities.

A device may include a receiver and a mixer. The receiver may provide a radio frequency (RF) signal to the mixer. The mixer may down-convert the RF signal to generate multiple baseband signals (e.g., an in-phase signal and a quadrature signal). The baseband signals may be filtered by an analog filter to generate filtered baseband signals. The mixer, the analog filter, or both, may cause an imbalance between an in-phase path corresponding to the in-phase signal and a quadrature path corresponding to the quadrature signal. The imbalance may cause self-interference, resulting in receiver performance loss.

### III. SUMMARY

In a particular aspect, a device for communication includes a receiver and a tuned infinite impulse response (IIR) compensation filter. The receiver is coupled to an in-phase path and a quadrature path. The tuned IIR compensation filter is coupled to one of the in-phase path and the quadrature path.

In another particular aspect, a method of communication includes receiving, at a mixer of a device, a radio frequency (RF) signal. The method also includes generating, at the mixer, an in-phase signal based on the RF signal. The method further includes generating, at the mixer, a quadrature signal based on the RF signal. The method further includes providing a signal based on one of the in-phase signal or the quadrature signal to a tuned infinite impulse response (IIR) compensation filter.

Other aspects, advantages, and features of the present disclosure will become apparent after review of the entire application, including the following sections: Brief Description of the Drawings, Detailed Description, and the Claims.

### IV. BRIEF DESCRIPTION OF THE DRAWINGS

FIG. 1 is a block diagram of a particular illustrative example of a device that includes a receiver coupled to a tuned IIR compensation filter;

FIG. 2 is a flowchart of a particular example of operation of the device of FIG. 1; and

FIG. 3 is a block diagram of a particular illustrative example of a device that includes a receiver coupled to a tuned IIR compensation filter.

### V. DETAILED DESCRIPTION

A device includes a receiver that is coupled to an IIR compensation filter. The receiver may include an orthogonal frequency-division multiplexing (OFDM) receiver. The receiver is configured to provide a radio frequency (RF) signal to a mixer. The mixer may generate multiple baseband signals (e.g., a first baseband signal and a second baseband signal) by down-converting the RF signal. One of the first baseband signal or the second baseband signal may correspond to an in-phase signal and the other of the first baseband signal or the second baseband signal may correspond to a quadrature signal.

The mixer may provide the first baseband signal to a first analog filter and may provide the second baseband signal to a second analog filter. The first analog filter may generate a first filtered baseband signal based on the first baseband signal and may provide the first filtered baseband signal to a first analog-to-digital converter (ADC). The second analog filter may generate a second filtered baseband signal based on the second baseband signal and may provide the second filtered baseband signal to a second ADC. The first analog filter may differ from the second analog filter due to process variations, causing a mismatch between the first filtered baseband signal and the second filtered baseband signal.

The first ADC may generate a first digital signal by converting the first filtered baseband signal and the second ADC may generate a second digital signal by converting the second filtered baseband signal. The mixer, the first analog filter, the second analog filter, or a combination thereof, may cause a mismatch between the first digital signal and the second digital signal. For example, a measure of a mismatch (e.g., an image rejection ratio) between the first digital signal and the second digital signal may fail to satisfy (e.g., is greater than or equal to) a threshold (e.g., 50 decibels). The first ADC may provide the first digital signal to a tuned IIR compensation filter. The tuned IIR compensation filter may generate a first compensated digital signal. The measure of a mismatch (e.g., an image rejection ratio) between the first compensated digital signal and the second digital signal may satisfy (e.g., is less than) the threshold (e.g., 50 decibels). The threshold may be defined in an industry standard, a specification, or both. The measure of mismatch satisfying the threshold may indicate that an imbalance between the in-phase path and the quadrature path has been reduced (e.g., eliminated), improving receiver performance.

The IIR compensation filter may be tuned based on channel response values of an in-phase channel (e.g., on an in-phase processing path) corresponding to the in-phase signal and of a quadrature channel (e.g., on a quadrature processing path) corresponding to the quadrature signal. For example, parameters of the IIR compensation filter may be based on model-fitting first channel response values corresponding to the in-phase path and second channel response values corresponding to the quadrature path.

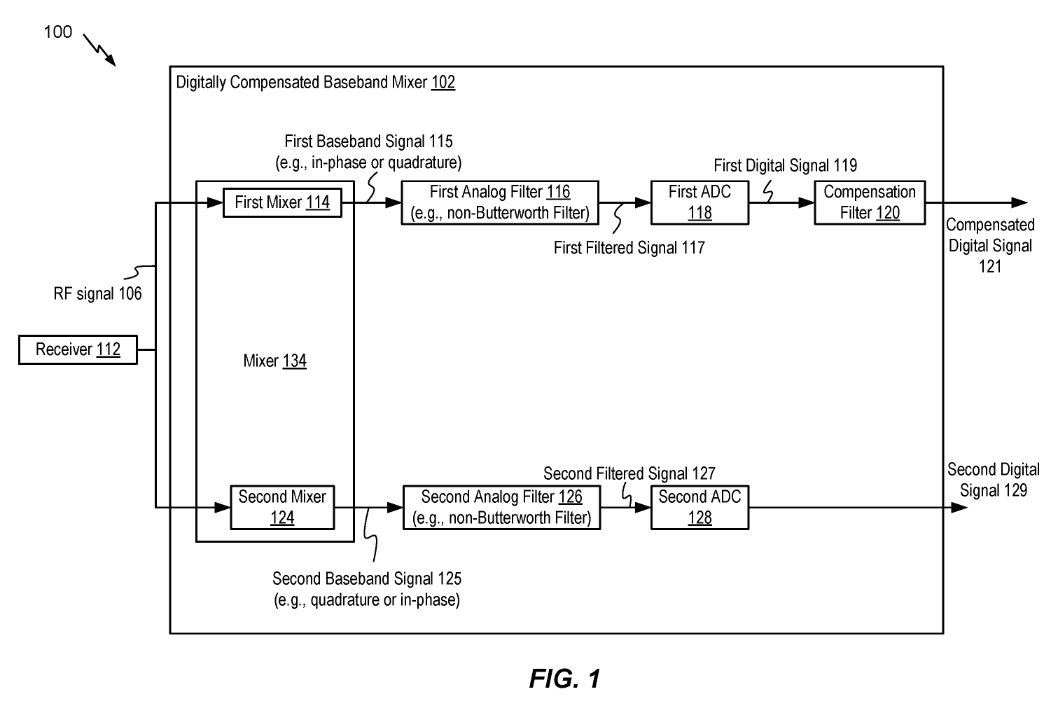

Referring to FIG. 1, a particular illustrative aspect of a device is disclosed and generally designated 100. The device 100 includes a receiver 112 coupled to a digitally compensated baseband mixer 102. The receiver 112 may include an orthogonal frequency-division multiplexing (OFDM) receiver, a wireless receiver, a long term evolution (LTE) receiver, another receiver, or a combination thereof. The digitally compensated baseband mixer 102 may include a mixer 134. The mixer 134 may include a first mixer 114 and a second mixer 124. The first mixer 114 may be coupled, via a first analog filter 116 (e.g., a non-Butterworth filter) and a first analog-to-digital converter (ADC) 118, to a compensation filter 120 (e.g., a 14-bit filter). The second mixer 124 may be coupled, via a second analog filter 126 (e.g., a non-Butterworth filter), to a second ADC 128.

The receiver 112 may be coupled to an in-phase path and a quadrature path. For example, one of the in-phase path or the quadrature path may include the first mixer 114, the first analog filter 116, the first ADC 118, or a combination thereof. The other of the in-phase path or the quadrature path may include the second mixer 124, the second analog filter 126, the second ADC 128, or a combination thereof. The compensation filter 120 may be coupled to the one of the in-phase path or the quadrature path. For example, the compensation filter 120 may be coupled to the first ADC 118. The compensation filter 120 may include a stabilized IIR filter. For example, poles of a transfer function of the compensation filter 120 (e.g., an IIR filter) may have a particular value (e.g., greater than or equal to 0 and less than 1) that satisfies a bounded-input bounded-output (BIBO) stability criterion.

During operation, the receiver 112 may provide a radio frequency (RF) signal 106 to the mixer 134. For example, the receiver 112 may provide the RF signal 106 to the first mixer 114 and to the second mixer 124. The first mixer 114 may generate a first baseband signal 115 (e.g., one of an in-phase signal or a quadrature signal) by down-converting the RF signal 106, and the second mixer 124 may generate a second baseband signal 125 (e.g., the other of the in-phase signal or a quadrature signal) by down-converting the RF signal 106. For example, the first mixer 114 may apply a first function to a carrier frequency of the RF signal 106 to generate the first baseband signal 115 and the second mixer 124 may apply a second function to the carrier frequency of the RF signal 106 to generate the second baseband signal 125.

In a particular aspect, the first function may include a cosine function, such as cos(ω_{C}t), and the second function may include a sine function, such as sin(ω_{C}t), where ω_{C} corresponds to the carrier frequency and t corresponds to time. The first baseband signal 115 may correspond to an in-phase signal and the second baseband signal 125 may correspond to a quadrature signal. In an alternate aspect, the first function may include the sine function and the second function may include the cosine function. The first baseband signal 115 may correspond to the quadrature signal and the second baseband signal 125 may correspond to the in-phase signal. The first baseband signal 115 may have a phase shift (e.g., a 90 degree phase shift) relative to the second baseband signal 125.

The first mixer 114 may provide the first baseband signal 115 to the first analog filter 116. The first analog filter 116 may generate a first filtered signal 117 by filtering the first baseband signal 115. The second mixer 124 may provide the second baseband signal 125 to the second analog filter 126. The second analog filter 126 may generate a second filtered signal 127 by filtering the second baseband signal 125.

The first analog filter 116 may provide the first filtered signal 117 to the first ADC 118. The first ADC 118 may generate a first digital signal 119 by performing an analog-to-digital conversion of the first filtered signal 117. The second analog filter 126 may provide the second filtered signal 127 to the second ADC 128. The second ADC 128 may generate a second digital signal 129 by performing an analog-to-digital conversion of the second filtered signal 127.

The first ADC 118 may provide the first digital signal 119 to the compensation filter 120. The compensation filter 120 may generate a compensated digital signal 121 by filtering the first digital signal 119. The image rejection ratio corresponding to the in-phase signal and the quadrature signal may be less than 50 decibels in an in-band frequency range (e.g., 0 megahertz (MHz)-10 MHz). For example, the image rejection ratio corresponding to the compensated digital signal 121 and the second digital signal 129 may be less than a decibel threshold (e.g., 50 decibels) in an in-band frequency range (e.g., 0 MHz-10 MHz).

The compensation filter 120 may be tuned to at least partially compensate for a mismatch between the first analog filter 116 and the second analog filter 126, e.g., due to production imperfections, temperature dependencies, etc. The first digital signal 119 may correspond to a first function (e.g., |Hᵢ(ω)| cos(ωt+θᵢ(w)+φ)). The second digital signal 129 may correspond to a second function (e.g., |H_{q}(ω)| sin(ωt+θ_{q}(w)+φ)). The compensation filter 120 may be tuned, e.g., during a tuning or calibration phase, based on channel response values corresponding to the in-phase path and the quadrature path. For example, parameters (e.g., Hᵢ/H_{q}) of the compensation filter 120 may be based on model fitting first channel response values (e.g., H) corresponding to the in-phase path and second channel response values (e.g., H_{q}) corresponding to the quadrature path. The first channel response values and the second channel response values may be based on sampling a subset of tones (e.g., 12 tones out of 64 tones) in an in-band frequency range (e.g., 0 MHz-10 MHz). Performing the model fitting based on sampling a greater number of tones in the in-band frequency range may result in a more accurate model while performing the model fitting based on sampling a fewer number of tones in the in-band frequency range may result in a reduced calibration or tuning delay. The model fitting may be based on a least squares approach (e.g., Levy's least squares approach).

In some implementations, the compensation filter 120 may be tuned by a tuning or calibration device, such as part of a manufacturing process. After tuning the compensation filter 120, the filter parameter values determined during tuning may be stored in a non-volatile memory (e.g., non-volatile latch, fuse array) to be accessible to the compensation filter 120. In some implementations, tuning of the compensation filter 120 may change over time because performance of the first analog filter 116, the second analog filter 126, or both, may change with use. For example, the compensation filter 120 may be re-tuned at various times as part of a maintenance process by a manufacturer or “in the field”. To illustrate, the device 100 may be configured to perform a calibration or tuning process to determine updated filter parameters, such as updated value(s) of Hᵢ/H_{q}.

The device 100 may thus enable providing the first digital signal 119 based on one of an in-phase signal or a quadrature signal to a tuned IIR compensation filter (e.g., the compensation filter 120). The compensation filter 120 may be configured to generate the compensated digital signal 121 such that an image rejection ratio between the compensated digital signal 121 and the second digital signal 129 is less than a decibel threshold (e.g., 50 decibels) in an in-band frequency range (e.g., 0 MHz-10 MHz). A first audio signal based on the compensated digital signal 121 and the second digital signal 129 may have less distortion as compared to a second audio signal based on the first digital signal 119 and the second digital signal 129.

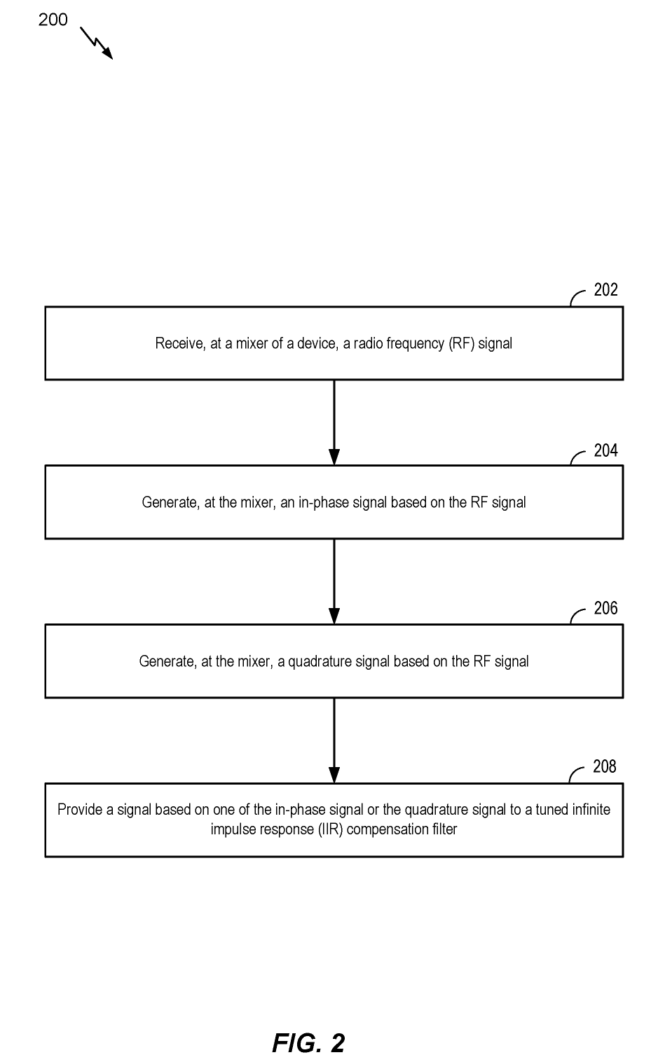

FIG. 2 is a flowchart illustrating a particular aspect of a method 200. The method 200 may be performed by the digitally compensated baseband mixer 102 of the device 100 of FIG. 1.

The method 200 includes receiving, at a mixer of a device, a radio frequency (RF) signal, at 202. For example, the mixer 134 of FIG. 1 may receive the RF signal 106 from the receiver 112.

The method 200 also includes generating, at the mixer, an in-phase signal based on the RF signal, at 204. For example, the mixer 134 of FIG. 1 may generate the first baseband signal 115 and the second baseband signal 125 based on the RF signal 106, as described with reference to FIG. 1. The first baseband signal 115 or the second baseband signal 125 may include an in-phase signal.

The method 200 further includes generating, at the mixer, a quadrature signal based on the RF signal, at 206. For example, the mixer 134 of FIG. 1 may generate the first baseband signal 115 and the second baseband signal 125 based on the RF signal 106, as described with reference to FIG. 1. The first baseband signal 115 or the second baseband signal 125 may include a quadrature signal.

The method 200 also includes providing a signal based on one of the in-phase signal or the quadrature signal to a tuned infinite impulse response (IIR) compensation filter, at 208. For example, the digitally compensated baseband mixer 102 of FIG. 1 may provide the first digital signal 119 to the compensation filter 120 (e.g., a tuned IIR compensation filter), as described with reference to FIG. 1. The first digital signal 119 may be based on one of the in-phase signal or the quadrature signal. To illustrate, the mixer 134 may provide the first baseband signal 115 to the first analog filter 116. The first analog filter 116 may generate the first filtered signal 117 based on the first baseband signal 115, as described with reference to FIG. 1. The first analog filter 116 may provide the first filtered signal 117 to the first ADC 118. The first ADC 118 may generate the first digital signal 119 based on the first filtered signal 117, as described with reference to FIG. 1. The first ADC 118 may provide the first digital signal 119 to the compensation filter 120.

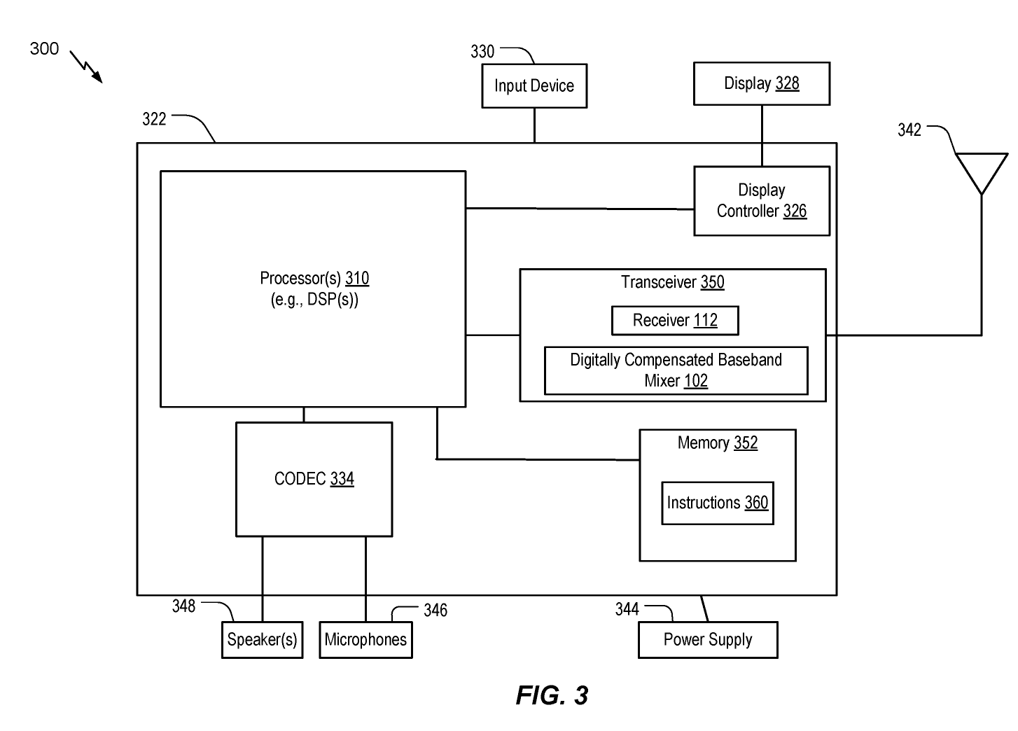

Referring to FIG. 3, a block diagram of a particular illustrative example of a device 300 (e.g., a wireless communication device) is shown. In various implementations, the device 300 may have more or fewer components than illustrated in FIG. 3. In an illustrative implementation, the device 300 may correspond to the device 100 of FIG. 1. In an illustrative implementation, the device 300 may operate according to the method 200 of FIG. 2.

In a particular implementation, the device 300 includes one or more processors 310. The processor(s) 310 may include a central processing unit (CPU), one or more digital signal processors (DSPs), or a combination thereof. The device 300 may include a memory 352 and a CODEC 334. The memory 352 may include instructions 360 that are executable by the processor(s) 310. The device 300 may include a transceiver 350 coupled to an antenna 342. The transceiver 350 may include the receiver 112, the digitally compensated baseband mixer 102, or both, of FIG. 1. The digitally compensated baseband mixer 102 may be implemented in hardware in conjunction with the techniques as described herein. The device 300 may include a display 328 coupled to a display controller 326. The device 300 may also include a microphone 346 and a speaker 348 coupled to the CODEC 334.

In a particular implementation, the device 300 may be included in a system-in-package or system-on-chip device 322. In a particular implementation, the memory 352, the processor(s) 310, the display controller 326, the CODEC 334, and the transceiver 350 are included in a system-in-package or system-on-chip device 322. In a particular implementation, an input device 330 and a power supply 344 are coupled to the system-on-chip device 322. Moreover, in a particular implementation, as illustrated in FIG. 3, the display 328, the input device 330, the speaker 348, the microphone 346, the antenna 342, and the power supply 344 are external to the system-on-chip device 322. In a particular implementation, each of the display 328, the input device 330, the speaker 348, the microphone 346, the antenna 342, and the power supply 344 may be coupled to a component of the system-on-chip device 322, such as an interface or a controller. The device 300 may include at least one of a mobile phone, a communication device, a computer, a music player, a video player, an entertainment unit, a navigation device, a personal digital assistant (PDA), a decoder, or a set top box.

In conjunction with the described implementations, an apparatus includes means for generating an in-phase signal and a quadrature signal based on a radio frequency (RF) signal. For example, the means for generating the in-phase signal and the quadrature signal may include the receiver 112, the mixer 134, the first mixer 114, the second mixer 124 of FIG. 1, or any combination thereof.

The apparatus also includes means for generating a compensated signal by applying a tuned infinite impulse response (IIR) compensation filter to one of the in-phase signal or the quadrature signal. For example, the means for generating the compensated signal may include the digitally compensated baseband mixer 102, the compensation filter 120, the device 100 of FIG. 1, the transceiver 350 of FIG. 3, or a combination thereof.

Those of skill would further appreciate that the various illustrative logical blocks, configurations, modules, circuits, and algorithm steps described in connection with the implementations disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, such implementation decisions are not to be interpreted as causing a departure from the scope of the present disclosure.

The steps of a method or algorithm described in connection with the implementations disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor may read information from, and write information to, the storage medium. In the alternative, the storage medium may be integral to the processor. The processor and the storage medium may reside in an ASIC. The ASIC may reside in a computing device or a user terminal. In the alternative, the processor and the storage medium may reside as discrete components in a computing device or user terminal.

The previous description of the disclosed aspects is provided to enable a person skilled in the art to make or use the disclosed aspects. Various modifications to these aspects will be readily apparent to those skilled in the art, and the principles defined herein may be applied to other aspects without departing from the scope of the disclosure. Thus, the present disclosure is not intended to be limited to the aspects shown herein but is to be accorded the widest scope possible consistent with the principles and novel features as defined by the following claims.

What is claimed is:

1. A device for communication comprising:
a receiver coupled to an in-phase path and a quadrature path; and
a tuned infinite impulse response (IIR) compensation filter coupled to one of the in-phase path or the quadrature path.

2. The device of claim 1, wherein the in-phase path includes:
a mixer coupled to the receiver, the mixer configured to generate an in-phase signal by down-converting a radio frequency (RF) signal received from the receiver;
an analog filter coupled to the mixer, the analog filter configured to generate a filtered in-phase signal by filtering the in-phase signal; and
an analog-to-digital converter (ADC) coupled to the analog filter, the ADC configured to generate a digital in-phase signal by converting the filtered in-phase signal.

3. The device of claim 2, wherein the analog filter includes a non-Butterworth filter.

4. The device of claim 2, wherein the ADC is further configured to provide the digital in-phase signal to the tuned IIR compensation filter.

5. The device of claim 1, wherein the quadrature path includes:
a mixer coupled to the receiver, the mixer configured to generate a quadrature signal by down-converting a radio frequency (RF) signal received from the receiver;
an analog filter coupled to the mixer, the analog filter configured to generate a filtered quadrature signal by filtering the quadrature signal; and
an analog-to-digital converter (ADC) coupled to the analog filter, the ADC configured to generate a digital quadrature signal by converting the filtered quadrature signal.

6. The device of claim 5, wherein the ADC is configured to provide the digital quadrature signal to the tuned IIR compensation filter.

7. The device of claim 5, wherein the analog filter includes a non-Butterworth filter.

8. The device of claim 1, wherein the tuned IIR compensation filter includes a stabilized IIR filter.

9. The device of claim 1, wherein the tuned IIR compensation filter includes a 14-bit filter.

10. The device of claim 1, wherein parameters of the tuned IIR compensation filter are based on model fitting first channel response values corresponding to the in-phase path and second channel response values corresponding to the quadrature path.

11. The device of claim 10, wherein the first channel response values are based on sampling a subset of tones in an in-band frequency range.

12. The device of claim 11, wherein the in-band frequency range is between 0 megahertz (MHz) and 10 MHz.

13. The device of claim 10, wherein the model fitting is based on a least squares approach.

14. The device of claim 1, wherein parameters of the tuned IIR compensation filter are based on model fitting a ratio of first channel response values and second channel response values, wherein the first channel response values correspond to the in-phase path, and wherein the second channel response values correspond to the quadrature path.

15. A method of communication comprising:
receiving, at a mixer of a device, a radio frequency (RF) signal;
generating, at the mixer, an in-phase signal based on the RF signal;
generating, at the mixer, a quadrature signal based on the RF signal; and
providing a signal based on one of the in-phase signal or the quadrature signal to a tuned infinite impulse response (IIR) compensation filter.

16. The method of claim 15, wherein an image rejection ratio corresponding to the in-phase signal and the quadrature signal is less than 50 decibels in an in-band frequency range, and wherein the in-band frequency range is between 0 megahertz (MHz) and 10 MHz.

17. The method of claim 16, further comprising generating a filtered signal by applying an analog filter to the one of the in-phase signal or the quadrature signal, wherein the signal is based on the filtered signal.

18. The method of claim 17, further comprising generating a digital signal by applying an analog-to-digital converter (ADC) to the filtered signal, wherein the signal includes the digital signal.

19. An apparatus comprising:
means for generating an in-phase signal and a quadrature signal based on a radio frequency (RF) signal; and
means for generating a compensated signal by applying a tuned infinite impulse response (IIR) compensation filter to one of the in-phase signal or the quadrature signal.

20. The apparatus of claim 19, wherein the means for generating the compensated signal and the means for generating the in-phase signal and the quadrature signal are integrated into at least one of at least one of a mobile phone, a communication device, a computer, a music player, a video player, an entertainment unit, a navigation device, a personal digital assistant (PDA), a decoder, or a set top box.
